(19) United States
(12) Patent Application Publication
(10) Pub. No.: US 2024/0112730 A1
(43) Pub. Date: Apr. 4, 2024

(54) DEVICE, METHOD AND SYSTEM TO PROVIDE A RANDOM ACCESS MEMORY WITH A FERROELECTRIC RESISTIVE JUNCTION

(71) Applicant: Intel Corporation, Santa CLara, CA (US)

(72) Inventors: Sou-Chi Chang, Portland, OR (US); Nazila Haratipour, Portland, OR (US); Saima Siddiqui, HIllsboro, OR (US); Uygar Avci, Portland, OR (US); Chia-Ching Lin, Portland, OR (US)

(73) Assignee: Intel Corporation, Santa Clara, CA (US)

(21) Appl. No.: 17/957,945

(22) Filed: Sep. 30, 2022

(51) Int. Cl. G11C 13/00; G11C 11/22; H01L 45/00

(52) U.S. Cl. CPC G11C 13/0026; G11C 11/22; G11C 13/0007; G11C 13/0028; G11C 13/0033; G11C 13/004; G11C 13/0069; H01L 45/1233; H01L 45/1253; H01L 45/146; G11C 2213/79

(57) ABSTRACT

Techniques and mechanisms for storing data with a memory cell which comprises a ferroelectric (FE) resistive junction. In an embodiment, a memory cell comprises a transistor and a FE resistive junction structure which is coupled to the transistor. The FE resistive junction structure comprises electrode structures, and a layer of a material which is between said electrode structures, wherein the material is a FE oxide or a FE semiconductor. The FE resistive junction structure selectively provides any of various levels of resistance, each to represent a respective one or more bits. A current flow through the FE resistive junction structure is characterized by thermionic emission through a Schottky barrier at an interface with one of the electrode structures. In another embodiment, the FE resistive junction structure further comprises one or more dielectric layers each between the layer of material and a different respective one of the electrode structures.

### BACKGROUND

### 1. Technical Field

This disclosure generally relates to memory devices and more particularly, but not exclusively, to a memory cell comprising a ferroelectric resistive junction.

### 2. Background Art

Most, if not all, logic devices require some type of random access memory. Resistive memories are non-volatile random access memories (NVRAMs) in which data is stored by resistive storage elements. Resistive random access memory (RRAM or ReRAM) works by changing the resistance across a dielectric solid-state material. A resistive memory element can be put in two states (e.g., high and low resistance) to store a bit data.

One type of resistive memory cell is a 1T1R (1 transistor, 1 resistor) memory cell. The 1T1R memory cell is composed of a resistive memory element that is connected in series with an access transistor, and the memory cell provides three terminals: word line (WL), bit line (BL) and source line (SL). Typically, 1T1R memory cells are arranged in columns, wherein each column shares the BL and SL terminals. Such a 1T1R memory cell is accessed during read/write operations by asserting the WL that turns on the access transistor. Reading from the memory cell is accomplished by sensing the resistance of the resistive memory element that is positioned between the BL and SL nodes. In the most common read technique, a fixed voltage is applied between the BL and SL nodes, and the current passing through the resistive memory element is measured by a sense amplifier.

One challenge in the design and use of resistive memory devices is the high current required to switch a given memory cell between a data bit 1 state and a data bit 0 state during a write operation. To date, these current requirements have limited the scaling of transistors such as those in 1T1R memory cells.

### BRIEF DESCRIPTION OF THE DRAWINGS

The various embodiments of the present invention are illustrated by way of example, and not by way of limitation, in the figures of the accompanying drawings and in which:

FIG. 1A shows a functional block diagram illustrating features of a memory device comprising a ferroelectric resistive memory element according to an embodiment.

FIG. 1B shows a circuit diagram illustrating features of a memory cell comprising a ferroelectric resistive junction according to an embodiment.

FIG. 2 shows a flow diagram illustrating features of a method to provide functionality of a resistive random access memory according to an embodiment.

FIG. 3 shows a cross-sectional side view diagram illustrating features of a memory device comprising a ferroelectric resistive junction according to an embodiment.

FIGS. 4A through 4F each a cross-sectional side view of a respective ferroelectric resistive junction of a memory cell according to a corresponding embodiment.

FIG. 5 shows a cross-sectional side view diagram illustrating features of a memory cell comprising a ferroelectric resistive junction according to an embodiment.

FIG. 6 is a functional block diagram illustrating a computing device in accordance with one embodiment.

FIG. 7 is a functional block diagram illustrating an exemplary computer system, in accordance with one embodiment.

### DETAILED DESCRIPTION

Embodiments discussed herein variously provide techniques and mechanisms for storing data with a memory cell which comprises a ferroelectric resistive junction structure. The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including one or more cells which each comprise a respective ferroelectric resistive junction structure that is to function as a resistive memory element.

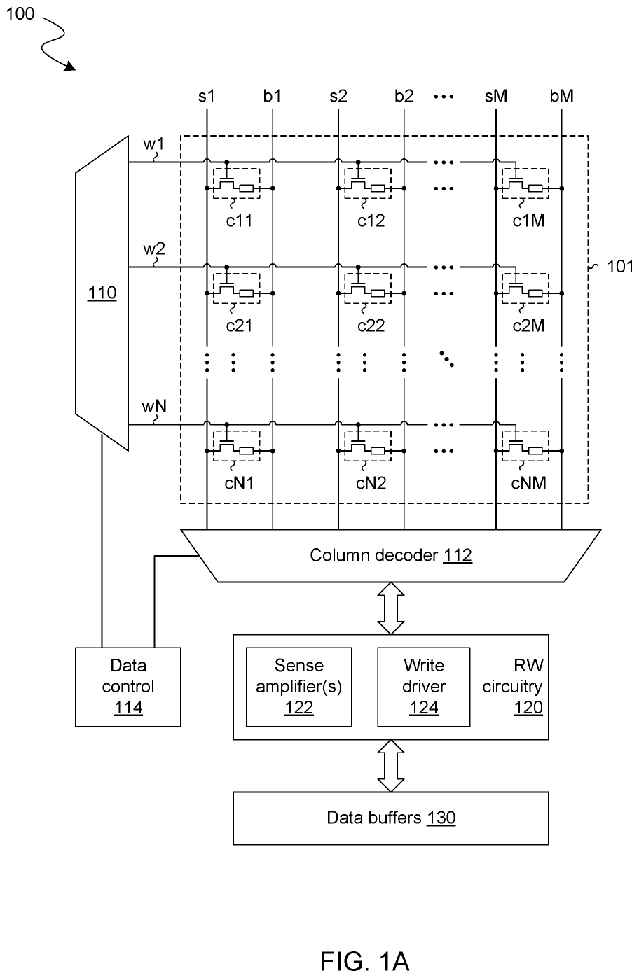

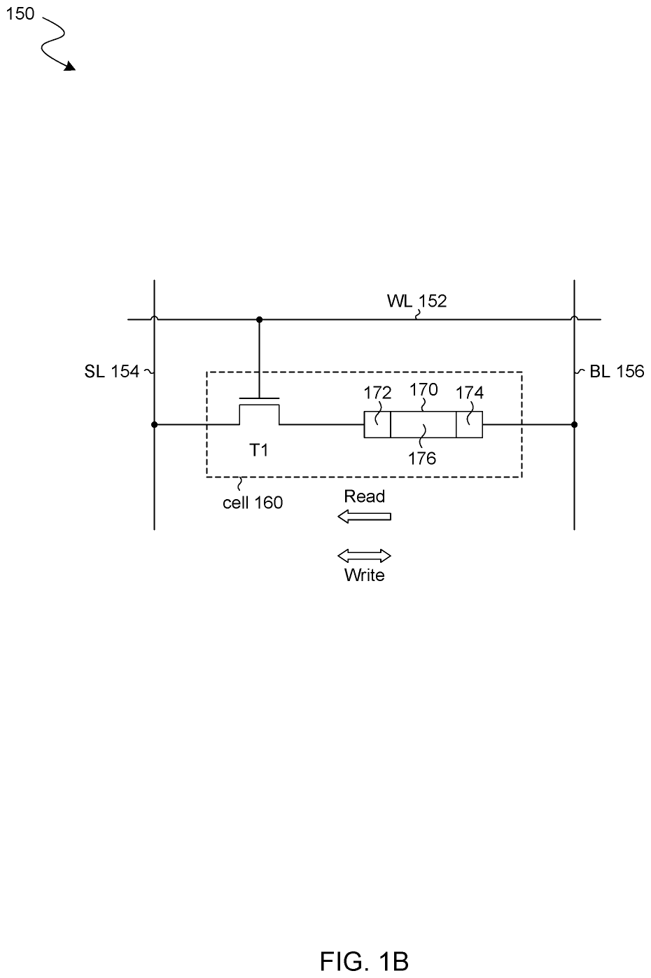

FIG. 1A illustrates a memory device 100 which provides a memory cell with a ferroelectric (FE) resistive junction structure according to an embodiment. In this particular context, “resistive junction” is to be distinguished, for example, from a “tunnel junction” through which electrons would pass via quantum tunneling. The FE resistive junction structure is a “strictly two terminal” structure—i.e., one which has two (and only two) terminals by which the structure is coupled to other structures of the memory array. Memory device 100 is one example of an embodiment wherein a memory cell comprises a transistor and a FE resistive junction structure which is to act as a resistive memory element.

As shown in FIG. 1A, memory device 100 comprises an array 101 of memory cells, a row decoder 110, a column decoder 112, read/write (RW) circuitry 120, data control 114, and data buffers 130. Cells of array 101 are arranged in an N×M matrix, with N cells in each column and M cells in each row. For example, each row corresponds to an M-bit word, wherein an ith column corresponds to the ith bit of each word, where 1≤i≤M.

The rows and columns of memory array 101 are variously accessible by respective word lines, select lines, and bit lines. For example, a given cell cXY of memory array 101 is accessible—in an Xth row and a Yth column (where X and Y are integers)—by a word line wX, a select line sY, and a bit line bY. In an embodiment, a first row of memory array 101 comprises cells c11, c12, . . . , c1M (where ‘M’ is an integer), wherein cell c11 is accessible by word line w1, select line s1, and bit line b1, and wherein cell c1M is accessible by word line w1, select line sM, and bit line bM. Furthermore, a second row of memory array 101 comprises cells c21, c22, . . . , c2M, wherein cell c21 is accessible by word line w2, select line s1, and bit line b1, and wherein cell c2M is accessible by word line w2, select line sM, and bit line bM. Further still, an Nth row of memory array 101 comprises cells cN1, cN2, . . . , cNM (where ‘N’ is an integer), wherein cell cN1 is accessible by word line wN, select line s1, and bit line b1, and wherein cell cNM is accessible by word line wN, select line sM, and bit line bM. The particular number of rows and columns in memory array 101, and the particular number of cells in a given row or column, is merely illustrative, and not limiting on some embodiments.

In some embodiments, a cell is selected by providing a row address and column address to row decoder 110 and column decoder 112, respectively. In some embodiments, row decoder 110 selectively activates a word line which is associated with a to-be selected cell. For example, N word lines w1, w2, . . . , wN are connected to row decoder 110, which decodes a row address signal and activates a corresponding word line, for either a read or a write operation. In one example scenario, row decoder 110 asserts word line w1 to select a cell from the first row of memory array 101—e.g., while other word lines (e.g., word lines w2 through wN) are de-asserted. Accordingly, a given word line activates M cells along a corresponding row of array 101. Thus, when the word line w2 is activated (for example), cells c21, c22, . . . , c2M are simultaneously accessible for read or write operations. Within each cell, the word line activates a respective transistor to enable access to a storage element of the cell.

The column decoder 112 decodes a column address signal to determine the accessing of a given cell by a corresponding bit line and select line. In some embodiments, column decoder 112 selectively accesses a bit line and/or a select line which is associated with a to-be selected cell. In an illustrative scenario, multiplexer circuitry of column decoder 112 enables communication between read/write (RW) circuitry 120 of memory device 100, and (for example) each of bit line b1 and select line s1. A given bit line and select line pair is thus selectively connected to read/write (RW) circuitry 120, which includes one or more sense amplifiers 122 (for read operations) and a write driver 124 (for write operations).

Data buffers 130 are connected to the RW circuitry 120. During a read operation, the column decoder 112 receives an output, via a given bit line and select line pair, and sends the output to the sense amplifier(s) 122, which amplify the signal and sends corresponding data to the data buffers 130, for receipt by external circuitry (not shown). During a write operation, the write driver 124 retrieves data from the data buffers 130 and sends an input to the relevant bit line and select line pair which corresponds to the column address signal, as selected by the column decoder 112.

In one embodiment, access to array 101 is further facilitated with a data control 114, which—for example—comprises integrated circuitry to receive a chip select (CS) signal, an output enable (OE) signal, a write enable (WE) signal and/or any of various other suitable signals to control operation of memory device 100. A chip select signal is provided where, for example, device 100 comprises a number of distinct chips, where a particular one such chip needs to be selected to be read from or written to. An output enable signal enables the data buffers 130, allowing data to be transferred to/from a memory cell. A write enable signal selects whether a read operation or a write operation is to take place. In some embodiments, such control signals are variously sent to row decoder 110 and/or column decoder 112—e.g., during every read or write operation.

In some embodiments, one or more cells of memory array 101 each comprise a resistive memory (RRAM) element and a select transistor—e.g., wherein one terminal of the RRAM element is coupled to a bit line and another terminal of the RRAM element is coupled to the select transistor. In some embodiments, the gate terminal of transistor is controllable by a word line, while the source/drain terminal of transistor is coupled to a select line. While array 101 is illustrated with reference to n-type select transistors for the cells, the cells can have p-type select transistors instead in accordance with some embodiments.

In some embodiments, the RRAM element of a given memory cell is (re)programmable or otherwise (re)configurable to provide any of multiple different resistances that depend on the selective provisioning of a conduction path with a ferroelectric resistive junction structure. In some embodiments, a cell is written with a logic high or logic low by adjusting the resistance of the cell's RRAM element. For example, the resistive element is SET to a first (e.g., low) resistance or RESET to a second (e.g., high) resistance to write a logic high and logic low, respectively, in the RRAM element. The different resistances can be interpreted as different binary values.

In some embodiments, to perform a SET function, the gate terminal of a transistor of the selected cell is set to logic high, by setting the word line for that cell to logic high, and the select line associated with that cell is set to logic low. When the voltage on the bit line is higher than the voltage on the select line, a current flows in a first direction through the RRAM element of the selected cell to adjust its resistance to a low resistance. This adjustment in resistance is non-volatile, and as such a logic level is stored in the RRAM element of the selected cell.

In some embodiments, to perform a RESET function, the gate terminal of transistor of the selected cell is set to logic high, by setting the word line for that cell to logic high, and the select line associated with that cell is set to logic high. In this example, the bit line is at logic low level. When the voltage on the select line is higher than the voltage on the bit line, a current flows in a second direction through the RRAM element of the selected cell to adjust its resistance to a high resistance. This adjustment in resistance is non-volatile, and as such a logic level is stored in the RRAM element of the selected cell.

FIG. 1B shows features of a memory array 150 which includes a ferroelectric resistive junction structure to operate as a data storage element of a memory cell according to an embodiment. Memory array 150 includes memory cells of array 101, for example.

As shown in FIG. 1B, memory array 150 comprises a memory cell 160 which is coupled to a bit line (BL) 156, a word line (WL) 152, and a select line (SL) 154. Memory cell 160 comprises a transistor T1, and a ferroelectric device 170 which is to function as a resistive memory element. The transistor T1 acts as a selector switch for enabling access to ferroelectric device 170, wherein ferroelectric device 170 is operable to provide any of multiple levels of resistance each to indicate a different respective one or more data bits.

In the example embodiment shown, memory cell 160 is a 1T1R (one transistor one resistor) cell, wherein a gate terminal of transistor T1 is coupled to word line WL word line WL 152, and wherein select line SL 154 is coupled to a source or drain terminal of transistor T1. Ferroelectric device 170 is coupled between bit line BL 156 and another source or drain terminal of transistor T1. For example, electrodes 172, 174 are each to provide a different respective terminal of ferroelectric device 170, wherein a resistive junction structure 176 of ferroelectric device 170 extends between electrodes 172, 174. In one such embodiment, transistor T1 is coupled to ferroelectric device 170 via electrode 172, wherein bit line BL 156 is coupled to ferroelectric device 170 via electrode 174. In other embodiments, memory cell 160 further comprises one or more additional transistors which further facilitate read access and/or write access to ferroelectric device 170.

As detailed herein, resistive junction structure 176 comprises one or more material layers, including at least one layer of a ferroelectric material, which provide a ferroelectric resistive junction between electrodes 172, 174. In various embodiments, a current flow through such a resistive junction is dominated or otherwise characterized by thermionic emission through the Schottky barrier at one or both of the interfaces between resistive junction structure 176 and electrodes 172, 174 (e.g., including a metal/semiconductor interface). In some embodiments, said current flow is additionally or alternatively characterized by drift and diffusion mechanism through a ferroelectric semiconductor of the resistive junction structure 176. An on/off ratio of memory cell 160 is determined at least in part by a barrier height induced by the polarization direction in a ferroelectric semiconductor of resistive junction structure 176, which can be very different when electrodes 172, 174 have different screening or depletion widths.

In providing the ferroelectric resistive junction structure 176 as a resistive memory element, some embodiments variously reduce the amount of current required to write to memory cell 160. The reduced write current requirements in turn relax various performance requirements for transistor T1, which (for example) enables further access transistor scaling, improved compatibility to BEOL transistor, and/or the like.

In the example embodiment shown, there is one read direction (illustrated by the arrow labeled “Read”), wherein a write operation can be in either of two directions bi-directional (illustrated by the double-headed arrow labeled “Write”). Therefore, memory cell 160 structure can be described as a 1T1R memory cell with unipolar “read” and bipolar “write.”

The memory cell 160 is read by precharging the bit line BL 156 to a suitable read voltage VRD and allowing it to decay through the cell 160 when the write line WL 152 is strobed with a voltage Vcc which turns on the transistor T1. In some embodiments, a reference voltage VBL, which is simultaneously drained using a reference cell, acts as the sense amplifier reference. In some embodiments, both the reference and the accessed bit line BL 156 are clamped (e.g., using a PMOS current source), so that a constant differential is maintained at the sense amplifier input even for very long access times.

In this example, a logical zero is represented by a high resistance state of ferroelectric device 170. Conversely a logical one is represented in this example by a low resistance state of ferroelectric device 170. Accordingly, if the precharge read voltage VRD decays to a relatively high value, a logical 0 (high resistance state) is indicated as being stored in ferroelectric device 170. Conversely, if the precharge read voltage VRD decays to a relatively low value, a logical 1 (low resistance state) is indicated as being stored in ferroelectric device 170. It is appreciated that, in other embodiments, a logical 0 may alternatively be represented by a low resistance state of ferroelectric device 170, wherein a logical 1 is conversely represented by a high resistance state of ferroelectric device 170.

To write into the memory cell 160, a bidirectional writing scheme controlled by write driver 124 (for example) is used. For example, in some embodiments, to write a logical 1 in ferroelectric device 170, bit line BL 156 is charged to Vcc and select line SL 154 is connected to ground so that a current is flowing from the bit line BL 156 to the select line SL 154 via ferroelectric device 170. Conversely, to write a logical 0 in ferroelectric device 170, a current with opposite direction is utilized. Accordingly, select line SL 154 at Vcc and bit line BL 156 at ground causes current to flow from the select line SL 154 to the bit line BL 156, the opposite direction.

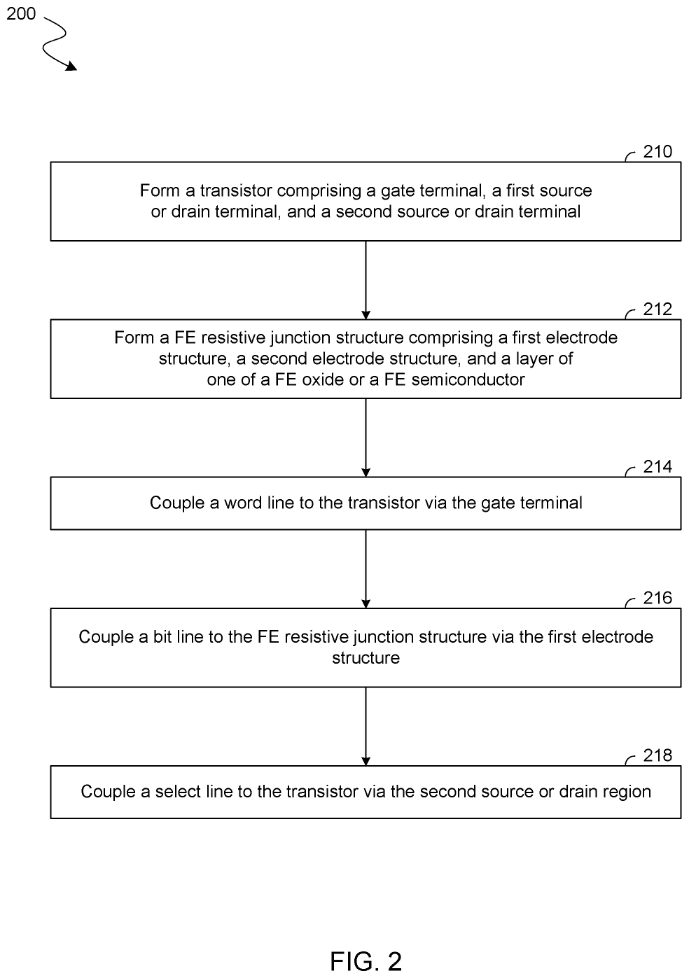

FIG. 2 illustrates a method for providing functionality of a memory cell which comprises a ferroelectric (FE) resistive junction according to an embodiment. Method 200 illustrates one embodiment which provides structures of a memory cell such as cell 160, or a cell of array 101. As shown in FIG. 2, method 200 comprises (at 210) forming a transistor of a memory cell, wherein the transistor comprises a gate terminal, a first source or drain terminal, and a second source or drain terminal. In some embodiments, the forming at 210 comprises one or more operations—e.g., adapted, for example, from conventional semiconductor processing—to fabricate structures of a non-planar transistor (or alternatively, a planar transistor) in or on a device layer of a semiconductor wafer. In one such embodiment, said one or more operations form the transistor T1 of memory cell 160, for example.

Method 200 further comprises (at 212) forming a FE resistive junction structure of the memory cell. For example, the FE resistive junction structure is formed at 212 by back end of line processing or (in some embodiments) by front end of line processing of the semiconductor wafer. By way of illustration and not limitation, the forming at 212 comprises fabricating ferroelectric device 170 of memory cell 160.

In some embodiments, the FE resistive junction structure comprises a first electrode structure, a second electrode structure, and a layer of a material between the first electrode structure and the second electrode structure (e.g., corresponding respectively to electrode 174, electrode 172, and resistive junction structure 176). The material is one of a FE oxide or a FE semiconductor, for example. In one such embodiment, the layer of material comprises a FE oxide which (for example) includes oxygen (O), and one of hafnium (Hf) or zirconium (Zr), and which further comprises a dopant such as one of silicon (Si), germanium (Ge), nitrogen (N), aluminum (Al), yttrium (Y), gadolinium (Gd), lanthanum (La), or strontium (Sr). For example, a stoichiometry of the FE oxide is substantially equal to that of hafnium oxide (HfO₂), of ZrO₂, or of any of various other suitable binary oxides which, when so doped, exhibit robust ferroelectricity (or antiferroelectricity, in some embodiments). In some embodiments, a thickness of the FE oxide is equal to or less than 5 nanometers (nm).

Additionally or alternatively, the layer of material comprises a FE semiconductor such as one which includes indium (In) and selenium (Se). In one embodiment, the FE semiconductor comprises any of various suitable polyvinylidene fluoride (PVDF) organic polymers, or (for example) any of various group IV monochalcogenides of the form MX—i.e., wherein M is germanium (Ge), or tin (Sn), and wherein X is sulfur (S), or selenium (Se). In another embodiment, the FE semiconductor comprises any of various other out-of-plane ferroelectric materials including (but not limited to) a 1T phase molybdenum disulfide (MoS₂), gallium arsenide (GaAs), or phosphorus oxide (P₂O₃). In still another embodiment, the FE semiconductor comprises any of various III2-VI3 compounds which are of the form A₂B₃—e.g., wherein A is aluminum (Al), gallium (Ga), or indium (In), and wherein B is sulfur (S), selenium (Se), or tellurium (Te). In some embodiments, a thickness of the FE semiconductor is in a range of 1 nm to 200 nm.

In some embodiments, the layer of a FE oxide or a FE semiconductor extends to each of the first electrode structure and the second electrode structure. In another embodiment, the FE resistive junction structure further comprises one or more dielectric layers which are each between said layer and a different respective one of the first electrode structure or the second electrode structure. For example, a given one such dielectric layer comprises an oxide of ruthenium (Ru), iridium (Jr), aluminum (Al), titanium (Ti), indium (In), gallium (Ga), zinc (Zn), tantalum (Ta), lanthanum (La), sodium (Na), cerium (Ce), niobium (Nb), or tungsten (W), in some embodiments. In some embodiments, a thickness of such a dielectric layer is equal to or less than 5 nanometers (nm). In one illustrative embodiment, a stoichiometry of one such dielectric layer is substantially equal to that of indium gallium zinc oxide (IGZO).

Method 200 further comprises (at 214) coupling a word line to the transistor via the gate terminal. For example, the coupling at 214 comprises performing metallization processes to form vias and/or other interconnect structures—e.g., whereby the gate of transistor T1 is coupled to word line WL 152. Method 200 further comprises (at 216) coupling a bit line to the FE resistive junction structure via the first electrode structure, wherein the first source or drain region is coupled to the second electrode structure. For example, the coupling at 216 comprises performing metallization processes to form interconnect structures whereby the bit line BL 156 is coupled to electrode 174. In one such embodiment, the same and/or other metallization processes couple a first source or drain of transistor T1 to ferroelectric device 170 via electrode 172. Method 200 further comprises (at 218) coupling a select line to the transistor via the second source or drain region. For example, the coupling at 218 comprises performing metallization processes to form interconnect structures whereby a second source or drain region of transistor T1 is coupled to select line SL 154.

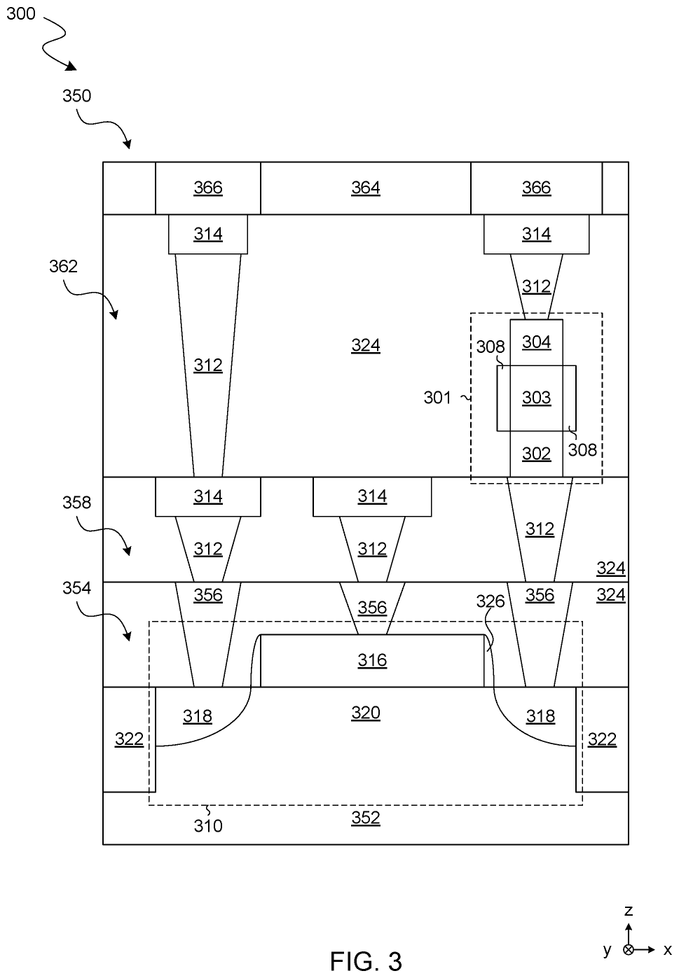

FIG. 3 shows a side-view illustration of a memory device 300 which includes a ferroelectric resistive junction structure as a resistive memory element according to an embodiment. In various embodiments, memory device 300 includes features of memory device 100 or memory array 150—e.g., wherein operations of method 200 are performed with memory device 300 and/or provide structures of memory device 300.

As shown in FIG. 3, memory device 300 comprises memory cell structures 350 which include structures of a memory cell such as cell 160, or a cell of array 101 (for example). In an embodiment, the memory cell comprises a transistor 310 and a resistive random access memory (RRAM) element 301 which, for example, correspond functionally to transistor T1 and ferroelectric device 170 (respectively) of memory cell 160. In the example embodiment shown, transistor 310 is a “front-end” transistor (i.e., formed as part of front-end fabrication operations), and the RRAM element 301 is a “back-end” structure (i.e., formed as part of back-end fabrication operations). Any of the embodiments of the components of the memory cell structures 350 illustrated in FIG. 3 (e.g., the conductive vias 312, the conductive lines 314) may be included in any of the memory cells disclosed herein.

The memory cell structures 350 are formed on a substrate 352 and, for example, may be included in a die. The substrate 352 may be a semiconductor substrate composed of semiconductor material systems including, for example, n-type or p-type material systems. The substrate 352 may include, for example, a crystalline substrate formed using a bulk silicon or a silicon-on-insulator substructure. In some embodiments, the semiconductor substrate 352 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the substrate 352. Although a few examples of materials from which the substrate 352 may be formed are described here, any material that may serve as a foundation for an memory cell structures 350 may be used. The substrate 352 may be part of a singulated die or a wafer.

The memory cell structures 350 may include structures in one or more device layers 354 disposed on the substrate 352. The device layer 354 may include features of transistor 310 (e.g., a metal oxide semiconductor field-effect transistor, or “MOSFET”) formed on the substrate 352. The device layer 354 may include, for example, one or more source and/or drain (S/D) regions 318, a gate 316 to control current flow in the channel 320 of the transistor 310 between the S/D regions 318, and one or more contacts 356 (which may take the form of conductive vias) to route electrical signals each to/from a respective one of the S/D regions 318 or gate 316. Adjacent transistors (not shown) may be isolated from each other by a shallow trench isolation (STI) insulating material 322, in some embodiments. Such transistors may include additional features not depicted for the sake of clarity, such as device isolation regions, gate contacts, and the like. Transistor 310 is not limited to the type and configuration depicted in FIG. 3 and may include a wide variety of other types and configurations such as, for example, a planar transistors, a nonplanar transistor, or a combination of both. Nonplanar transistors may include FinFET transistors, such as double-gate transistors or tri-gate transistors, and wrap-around or all-around gate transistors, such as nanoribbon and nanowire transistors.

In an embodiment, transistor 310 includes a gate 316 comprising a gate dielectric and a gate electrode. The gate electrode of the transistor 310 may include at least one p-type work function metal or n-type work function metal, depending on whether the transistor 310 is to be a p-type metal oxide semiconductor (PMOS) transistor or an n-type metal oxide semiconductor (NMOS) transistor. For a PMOS transistor, metals that may be used for the gate electrode of the transistor 310 may include, but are not limited to, ruthenium, palladium, platinum, cobalt, nickel, and conductive metal oxides (e.g., ruthenium oxide). For an NMOS transistor, metals that may be used for the gate electrode of the transistor 310 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode of the transistor 310 may consist of a stack of two or more metal layers, where one or more metal layers are work function metal layers and at least one metal layer is a fill metal layer. Further metal layers may be included for other purposes, such as to act as a barrier layer.

The gate dielectric of the transistor 310 may be, for example, silicon oxide, aluminum oxide, or a high-k dielectric, such as hafnium oxide. More generally, the gate dielectric of the transistor 310 may include elements such as hafnium, silicon, oxygen, titanium, tantalum, lanthanum, aluminum, zirconium, barium, strontium, yttrium, lead, scandium, niobium, and zinc. Examples of materials that may be used in the gate dielectric of the transistor 310 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate dielectric of the transistor 310 to improve the quality of the gate dielectric of the transistor 310.

In some embodiments, when viewed as a cross section of the transistor 310 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode of the transistor 310 may simply be a planar layer that is substantially parallel to the top surface of the substrate and does not include sidewall portions substantially perpendicular to the top surface of the substrate. In other embodiments, the gate electrode of the transistor 310 may consist of a combination of U-shaped structures and planar non-U-shaped structures. For example, the gate electrode of the transistor 310 may consist of one or more U-shaped metal layers formed atop one or more planar non-U-shaped layers. In some embodiments, the gate electrode may consist of a V-shaped structure.

In some embodiments, a pair of sidewall spacers 326 may be formed on opposing sides of the gate 316 to bracket the gate 316. The sidewall spacers 326 may be formed from a material such as silicon nitride, silicon oxide, silicon carbide, silicon nitride doped with carbon, and silicon oxynitride. Processes for forming sidewall spacers 326 are well known in the art and generally include deposition and etching process steps. In some embodiments, multiple pairs of sidewall spacers 326 may be used; for instance, two pairs, three pairs, or four pairs of sidewall spacers 326 may be formed on opposing sides of the gate stack.

The S/D regions 318 may be formed within the substrate 352 adjacent to the gate 316 of each transistor 310. For example, the S/D regions 318 may be formed using either an implantation/diffusion process or a deposition process. In the former process, dopants such as boron, aluminum, antimony, phosphorous, or arsenic may be ion-implanted into the substrate 352 to form the S/D regions 318. An annealing process that activates the dopants and causes them to diffuse farther into the substrate 352 may follow the ion-implantation process. In the latter process, an epitaxial deposition process may provide material that is used to fabricate the S/D regions 318. In some implementations, the S/D regions 318 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 318 may be formed using one or more alternate semiconductor materials such as germanium or a group III-V material or alloy. In further embodiments, one or more layers of metal and/or metal alloys may be used to form the S/D regions 318. In some embodiments, an etch process may be performed before the epitaxial deposition to create recesses in the substrate 352 in which the material for the S/D regions 318 is deposited.

Electrical signals, such as power and/or input/output (I/O) signals, may be routed to and/or from the transistor 310 of the device layer 354, and/or to and/or from the RRAM element 301, through one or more interconnect layers disposed on the device layer 354 (illustrated in FIG. 3 as interconnect layers 358 and 362). For example, electrically conductive features of the device layer 354 (e.g., the gate 316 and the contacts 356) and/or the RRAM element 301 (e.g., the FE resistive junction structure 303 and the electrodes 302, 304) may be electrically coupled with the interconnect structures including conductive vias 312 and/or conductive lines 314 of the interconnect layers 358 and 362. The one or more interconnect layers 358 and 362 may form an interlayer dielectric (ILD) stack of the memory cell structures 350. As discussed herein, the RRAM element 301 may itself be included in the ILD stack as a “back-end” device.

The interconnect structures may be arranged within the interconnect layers 358 and 362 to route electrical signals according to a wide variety of designs (in particular, the arrangement is not limited to the particular configuration of interconnect structures depicted in FIG. 3). Although a particular number of interconnect layers is depicted in FIG. 3, embodiments of the present disclosure include electronic devices having more or fewer interconnect layers than depicted.

In some embodiments, the interconnect structures may include conductive lines 314 (sometimes referred to as “trench structures”) and/or conductive vias 312 (sometimes referred to as “holes”) filled with an electrically conductive material such as a metal. The conductive lines 314 may be arranged to route electrical signals in a direction of a plane that is substantially parallel with a surface of the substrate 352 upon which the device layer 354 is formed. For example, the conductive lines 314 may route electrical signals in a direction in and out of the page from the perspective of FIG. 3. The conductive vias 312 may be arranged to route electrical signals in a direction of a plane that is substantially perpendicular to the surface of the substrate 352 upon which the device layer 354 is formed. In some embodiments, the conductive vias 312 may electrically couple conductive lines 314 of different interconnect layers 358 and 362 together.

The interconnect layers 358 and 362 may include an insulating material 324 disposed between the interconnect structures, as shown in FIG. 3. In some embodiments, the insulating material 324 disposed between the interconnect structures in different ones of the interconnect layers 358 and 362 may have different compositions; in other embodiments, the composition of the insulating material 324 between different interconnect layers 358 and 362 may be the same. The insulating material 324 may be a dielectric material, such as silicon dioxide. In some embodiments, the insulating material 324 may be any suitable interlayer dielectric (ILD) material.

A first interconnect layer 358 (referred to as Metal 1 or “M1”) may be formed directly on the device layer 354. In some embodiments, the first interconnect layer 358 may include conductive lines 314 and/or conductive vias 312, as shown. The conductive lines 314 of the first interconnect layer 358 may be coupled with contacts (e.g., the contacts 356) of the device layer 354.

A second interconnect layer 362 (referred to as Metal 2 or “M2”) may be formed directly on the first interconnect layer 358. In some embodiments, the second interconnect layer 362 may include conductive vias 312 to couple the conductive lines 314 of the second interconnect layer 362 with the conductive lines 314 of the first interconnect layer 358. Although the conductive lines 314 and the conductive vias 312 are structurally delineated with a line within each interconnect layer (e.g., within the second interconnect layer 362) for the sake of clarity, the conductive lines 314 and the conductive vias 312 may be structurally and/or materially contiguous (e.g., simultaneously filled during a dual-damascene process) in some embodiments.

Additional interconnect layers may be formed in succession on the second interconnect layer 362 according to similar techniques and configurations described in connection with the first interconnect layer 358 or the second interconnect layer 362.

In an embodiment, memory device 300 further comprises a solder resist material 364 (e.g., polyimide or similar material) and one or more bond pads 366 formed on the interconnect layers. The bond pads 366 may be electrically coupled with the interconnect structures and may route the electrical signals of the memory cell structures 350 to other external devices. For example, solder bonds may be formed on the one or more bond pads 366 to mechanically and/or electrically couple a chip including the memory cell structures 350 with another component (e.g., a circuit board). The memory cell structures 350 may include other structures to route the electrical signals from the interconnect layers than depicted in other embodiments. For example, the bond pads 366 may be replaced by or may further include other analogous features (e.g., posts) that route electrical signals to external components.

As noted above, the memory cell structures 350 may include a RRAM element 301, which may be electrically coupled to a transistor 310. The RRAM element 301 is illustrated as being included in the second interconnect layer 362, but the RRAM element 301 may be located in any suitable interconnect layer or other portion of the memory cell structures 350. RRAM element 301 comprises a ferroelectric (FE) resistive junction structure 303 and electrodes 302, 304—e.g., corresponding functionally to electrodes 172, 174—at opposite respective ends of FE resistive junction structure 303. In one such embodiment, sidewall structures 308 extend along (and, for example, around) FE resistive junction structure 303—e.g., wherein sidewall structures 308 comprises any of various suitable dielectric materials. Electrodes 302, 304 each provide a respective terminal of RRAM element 301—e.g., wherein RRAM element 301 is coupled to transistor 310 via electrode 302, and is further coupled to a bit line (such as BL 156) via electrode 302.

FE resistive junction structure 303 comprises one or more material layers, including at least one layer of a ferroelectric material, which are operable to provide a variable resistance between electrodes 302, 304. In various embodiments, a current flow through such a resistive junction structure is dominated by thermionic emission through the Schottky barrier at a given interface between FE resistive junction structure 303 and one of electrodes 302, 304. In some embodiments, such current flow is additionally or alternatively characterized by a drift and diffusion mechanism through a ferroelectric semiconductor of the FE resistive junction structure 303. In providing the FE resistive junction structure 303 as a resistive memory element, some embodiments variously reduce the amount of current required to write to a memory cell such as that illustrated by memory cell structures 350. The reduced write current requirements in turn relax various performance requirements for transistor 310, which (for example) enables further transistor scaling, improved compatibility to BEOL structures, and/or the like.

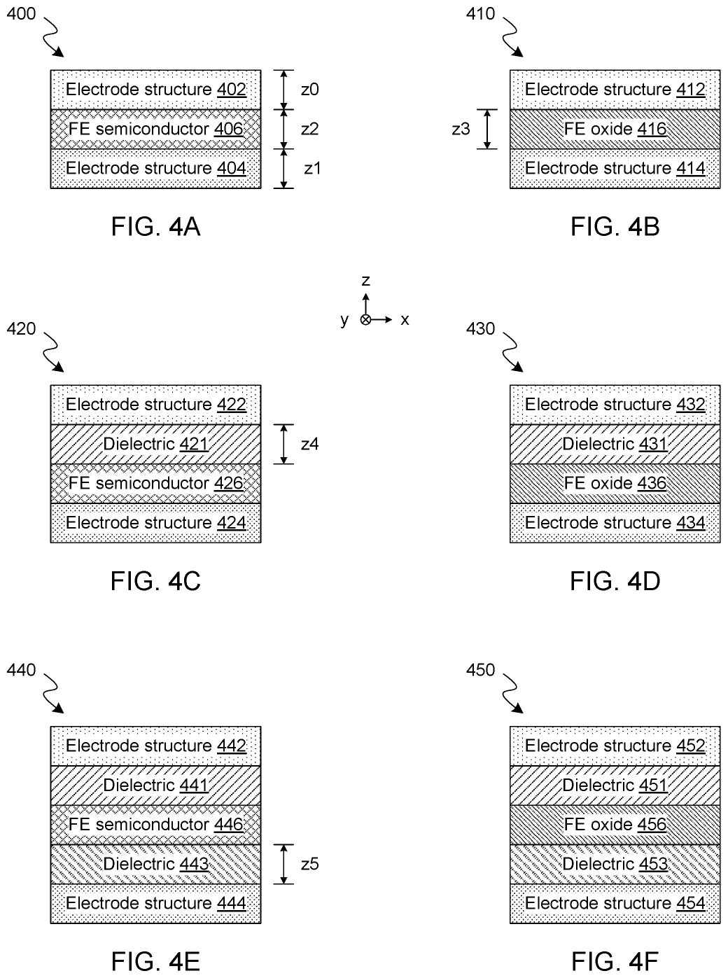

FIGS. 4A through 4F show cross-sectional side views of respective ferroelectric (FE) devices 400, 410, 420, 430, 440, 450 which are each to function as a resistive memory element according to a corresponding embodiment. FE devices 400, 410, 420, 430, 440, 450 each illustrate a respective embodiment which provides a FE resistive junction such as that of a 1T1R memory cell. In some embodiments, a given one of FE devices 400, 410, 420, 430, 440, 450 provides functionality such as that of ferroelectric device 170 or RRAM element 301—e.g., wherein such a FE device is provided and/or operated according to operations of method 200.

As shown in FIG. 4A, FE device 400 comprises a layer of a FE semiconductor 406 and electrode structures 402, 404 which are on opposite respective sides of FE semiconductor 406. In some embodiments, electrode structures 402, 404 each provide a respective terminal by which FE device 400 is to be coupled to other structures of a memory cell (e.g., wherein electrode structures 402, 404 correspond functionally to electrodes 172, 174, and wherein FE semiconductor 406 provides functionality of resistive junction structure 176). In one such embodiment, a given one of electrode structures 402, 404 comprises any of various suitable metal materials including (but not limited to) titanium nitride (TiN), tungsten (W), tantalum nitride (TaN), ruthenium (Ru), iridium (Ir), aluminum (Al), copper (Cu), titanium (Ti), cobalt (Co), chromium (Cr), molybdenum (Mo), nickel (Ni), gold (Au), platinum (Pt), or combinations thereof.

Additionally or alternatively, a given one of electrode structures 402, 404 comprises any of various suitable doped semiconductor materials including (but not limited to) silicon (Si), germanium (Ge), gallium arsenide (GaAs), or combinations thereof. For example, a semiconductor material of one of electrode structures 402, 404 is doped with arsenic, phosphorus, boron, or gallium—e.g., wherein the doping level is equal to or greater than higher than 10¹⁶ cm⁻³.

In various embodiments, FE semiconductor 406 comprises indium (In) and selenium (Se)—e.g., wherein FE semiconductor 406 includes indium selenide (In₂Se₃) which, for example, is in an alpha phase. In an illustrative scenario according to one embodiment, a (z-axis) thickness z0 of electrode structure 402, and/or a thickness z1 of electrode structure 404, is in a range of 5 nanometers (nm) to 30 nm—e.g., wherein a (z-axis) thickness z2 of FE semiconductor 406 is in a range of 3 nm to 70 nm.

As shown in FIG. 4B, FE device 410 comprises a layer of a FE oxide 416 and electrode structures 412, 414 which are on opposite respective sides of FE oxide 416. Electrode structures 412, 414 include some or all of the features of electrode structures 402, 404, for example. In various embodiments, FE oxide 416 comprises hafnium (Hf), oxygen (O), and a dopant material. For example, a stoichiometry of FE oxide 416 is substantially the same as that of ferroelectric hafnium oxide (HfO₂) which is doped with any of various suitable dopants including (but not limited to) silicon (Si), germanium (Ge), nitrogen (N), aluminum (Al), yttrium (Y), gadolinium (Gd), lanthanum (La), or combinations thereof. For example, a level of doping of FE oxide 416 is less than 15%, in some embodiments. In another embodiment, FE oxide 416 comprises hafnium (Hf), zirconium (Zr) and oxygen—e.g., wherein a stoichiometry of FE oxide 416 is substantially the same as that of a superlattice of hafnium oxide (HfO₂) and zirconium oxide (ZrO₂). In one example embodiment, a (z-axis) thickness z3 of FE oxide 416 is in a range of 0.5 nm or less—e.g., wherein respective thicknesses of electrode structures 412, 414 are each in a range of 5 nm to 30 nm.

As shown in FIG. 4C, FE device 420 comprises electrode structures 422, 424, as well as a layer of a FE semiconductor 426 and a layer of a dielectric 421, which are variously disposed between electrode structures 422, 424. In an embodiment, electrode structures 422, 424 include some or all of the features of electrode structures 402, 404—e.g., wherein FE semiconductor 426 includes some or all of the features of FE semiconductor 406.

In an embodiment, dielectric 421 comprises any of various suitable oxide (or other) insulator materials. By way of illustration and not limitation, dielectric 421 comprises oxygen (O), ruthenium (Ru), iridium (Jr), aluminum (Al), titanium (Ti), indium (In), gallium (Ga), zinc (Zn), tantalum (Ta), lanthanum (La), sodium (Na), or combinations thereof. For example, a stoichiometry of dielectric 421 is substantially the same as that of RuO₂, IrO₂, Al₂O₃, TiO₂, IGZO, In₂O₃, Ta₂O₃, La₂O₃, or Na₂O₅. In one example embodiment, a (z-axis) thickness z4 of dielectric 421 is in a range of 5 nm or less—e.g., wherein a thickness of FE semiconductor 426 is in a range of 3 nm to 70 nm, and wherein respective thicknesses of electrode structures 422, 424 are each in a range of 5 nm to 30 nm.

As shown in FIG. 4D, FE device 430 comprises electrode structures 432, 434, as well as a layer of a FE oxide 436 and a layer of a dielectric 431, which are variously disposed between electrode structures 432, 434. In an embodiment, electrode structures 432, 434 include some or all of the features of electrode structures 402, 404—e.g., wherein FE oxide 436 includes some or all of the features of FE oxide 416, and/or dielectric 431 includes some or all of the features of dielectric 421. In one example embodiment, a (z-axis) thickness of FE oxide 436 is in a range of 0.5 nm or less, and a thickness of dielectric 431 is in a range of 5 nm or less—e.g., wherein respective thicknesses of electrode structures 432, 434 are each in a range of 5 nm to 30 nm.

As shown in FIG. 4E, FE device 440 comprises electrode structures 442, 444, as well as a FE semiconductor 446, a dielectric 441, and a dielectric 443, which are variously disposed between electrode structures 442, 444. For example, dielectric 441, and dielectric 443 are each between (and, for example, extend to) FE semiconductor 446 and a different respective one of electrode structures 442, 444. In an embodiment, electrode structures 442, 444 include some or all of the features of electrode structures 422, 424—e.g., wherein FE semiconductor 446 includes some or all of the features of FE semiconductor 426, and/or one or each of dielectrics 441, 443 include some or all of the features of dielectric 421. In one example embodiment, a (z-axis) thickness z5 of dielectric 443 is in a range of 5 nm or less—e.g., wherein a thickness of dielectric 441 is in a range of 5 nm or less, a thickness of FE semiconductor 446 is in a range of 3 nm to 70 nm, and wherein respective thicknesses of electrode structures 442, 444 are each in a range of 5 nm to 30 nm.

As shown in FIG. 4F, FE device 450 comprises electrode structures 452, 454, as well as a FE oxide 456, a dielectric 451, and a dielectric 453, which are variously disposed between electrode structures 452, 454. For example, dielectric 451, and dielectric 453 are each between (and, for example, extend to) FE oxide 456 and a different respective one of electrode structures 452, 454. In an embodiment, electrode structures 452, 454 include some or all of the features of electrode structures 432, 434—e.g., wherein FE oxide 456 includes some or all of the features of FE oxide 436, and/or one or each of dielectrics 451, 453 include some or all of the features of dielectric 431. In one example embodiment, a (z-axis) thickness of dielectric 453 is in a range of 5 nm or less—e.g., wherein a thickness of dielectric 451 is in a range of 5 nm or less, a thickness of FE oxide 456 is in a range of 0.5 nm or less, and wherein respective thicknesses of electrode structures 452, 454 are each in a range of 5 nm to 30 nm.

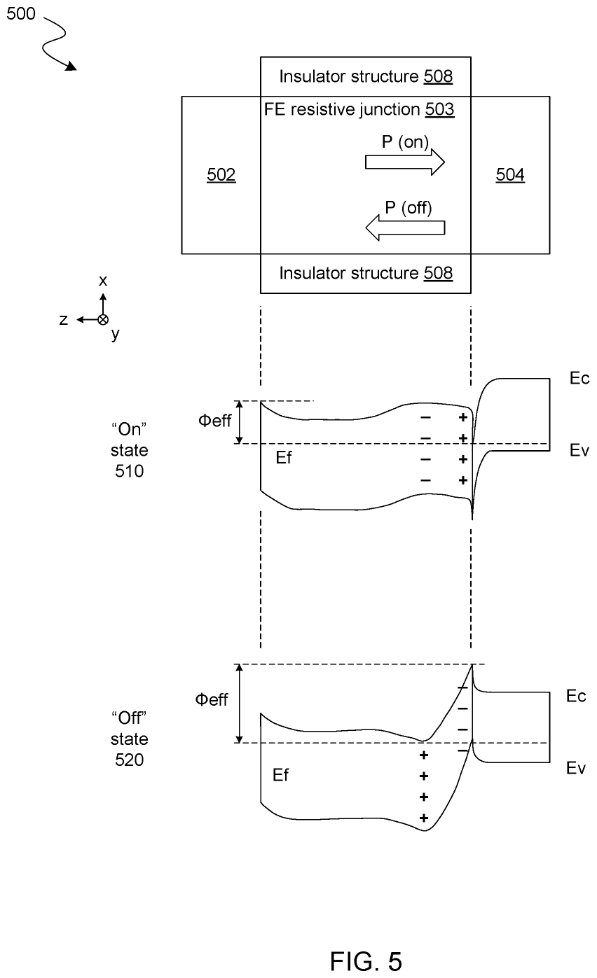

FIG. 5 shows features of a memory cell 500 which includes a ferroelectric device as a resistive memory element according to an embodiment. Memory cell 500 illustrates one embodiment which comprises a FE resistive junction structure and a transistor (not shown) which is coupled thereto. In one embodiment, memory cell 500 is a cell of memory array 101. For example, memory cell 500 includes features of memory array 150, memory cell structures 350 or one of FE devices 400, 410, 420, 430, 440, 450—e.g., wherein functionality of memory cell 500 is provided according to operations of method 200.

As shown in FIG. 5, memory cell 500 comprises a FE resistive junction structure 503 and electrode structures 502, 504 on opposite respective sides of FE resistive junction structure 503. In one such embodiment, an insulator structure 508 extends along (and, for example, around) FE resistive junction structure 503—e.g., wherein FE resistive junction structure 503 and insulator structure 508 correspond functionally to FE resistive junction structure 303 and sidewall structures 308 (respectively), and wherein electrode structures 502, 504 correspond functionally to electrodes 302, 304.

In one example embodiment, FE resistive junction structure 503 comprises indium and selenium—e.g., wherein a stoichiometry of FE resistive junction structure 503 is substantially the same as that of indium selenide (In₂Se₃) which, for example, is in an alpha phase. Alternatively or in addition, insulator structure 508 comprises any of various suitable dielectric materials such as aluminum oxide (Al₂O₃), for example. In one such embodiment, electrode structure 502 comprises nickel, gold, or any of various other suitable metals—e.g., wherein electrode structure 504 comprises a p+ doped silicon.

FIG. 5 further shows band diagrams 510, 520 which illustrate—for an “on” (relatively low impedance) state of memory cell 500, and an “off” (relatively high impedance) state of memory cell 500, respectively—valence band Ev, conduction band Ec, and Fermi level Ef characteristics along a (z-axis) height of memory cell 500. As illustrated in band diagram 510, the “on” state for memory cell 500 results from a relatively small band shift Φeff, which is due at least in part to a deletion region at an interface of FE resistive junction structure 503 and electrode structure 504. By contrast, as illustrated in band diagram 520, the “off” state for memory cell 500 results from a relatively large band shift Φeff, which is due at least in part to an accumulation region at the interface of FE resistive junction structure 503 and electrode structure 504.

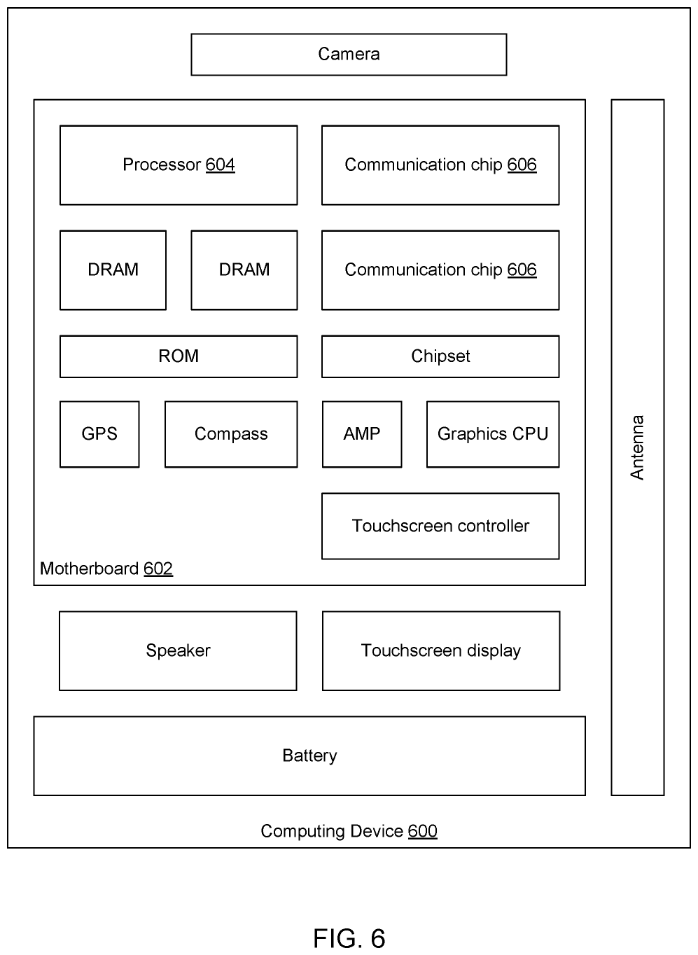

FIG. 6 illustrates a computing device 600 in accordance with one embodiment. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. The term “processor” may refer to any device or portion of a device that processes electronic data from registers and/or memory to transform that electronic data into other electronic data that may be stored in registers and/or memory. The communication chip 606 also includes an integrated circuit die packaged within the communication chip 606.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Some embodiments may be provided as a computer program product, or software, that may include a machine-readable medium having stored thereon instructions, which may be used to program a computer system (or other electronic devices) to perform a process according to an embodiment. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

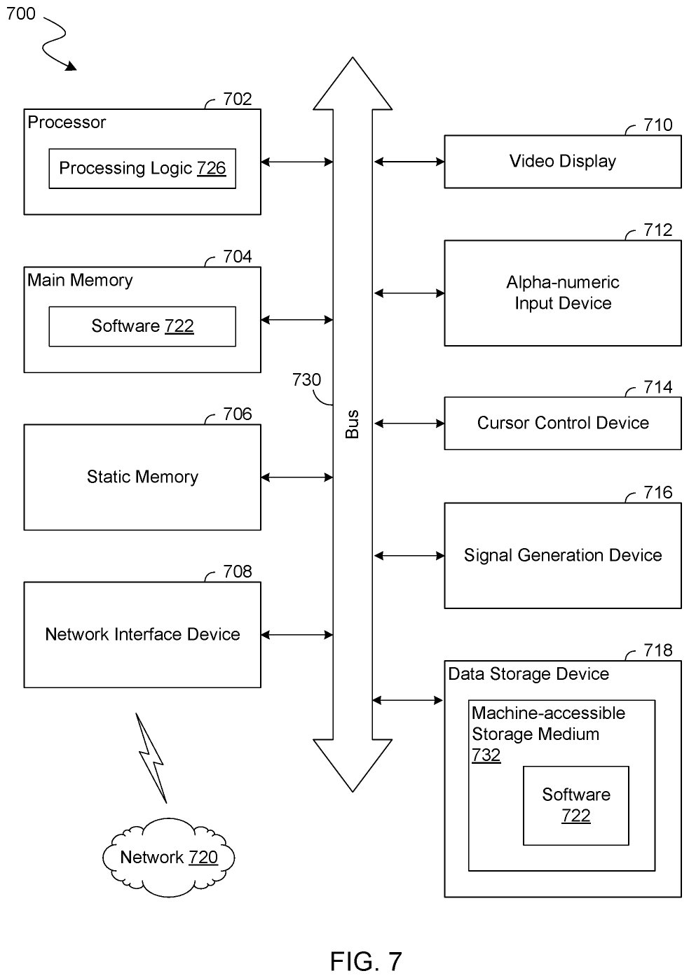

FIG. 7 illustrates a diagrammatic representation of a machine in the exemplary form of a computer system 700 within which a set of instructions, for causing the machine to perform any one or more of the methodologies described herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies described herein.

The exemplary computer system 700 includes a processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

Processor 702 represents one or more general-purpose processing devices such as a microprocessor, central processing unit, or the like. More particularly, the processor 702 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 702 may also be one or more special-purpose processing devices such as an application specific integrated circuit (ASIC), a field programmable gate array (FPGA), a digital signal processor (DSP), network processor, or the like. Processor 702 is configured to execute the processing logic 726 for performing the operations described herein.

The computer system 700 may further include a network interface device 708. The computer system 700 also may include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium (or more specifically a computer-readable storage medium) 732 on which is stored one or more sets of instructions (e.g., software 722) embodying any one or more of the methodologies or functions described herein. The software 722 may also reside, completely or at least partially, within the main memory 704 and/or within the processor 702 during execution thereof by the computer system 700, the main memory 704 and the processor 702 also constituting machine-readable storage media. The software 722 may further be transmitted or received over a network 720 via the network interface device 708.

While the machine-accessible storage medium 732 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any of one or more embodiments. The term “machine-readable storage medium” shall accordingly be taken to include, but not be limited to, solid-state memories, and optical and magnetic media.

In the following description, numerous details are discussed to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

In one or more first embodiments, a memory device comprises a memory cell comprising a transistor, a ferroelectric (FE) resistive junction structure coupled to the transistor, the FE resistive junction structure comprising a first electrode structure, a second electrode structure, and a layer of one of a FE oxide or a FE semiconductor between the first electrode structure and the second electrode structure.

In one or more second embodiments, further to the first embodiment, the transistor comprises a gate terminal, a first source or drain terminal, and a second source or drain terminal, the memory device further comprises a word line coupled to the transistor via the gate terminal, a bit line coupled to the FE resistive junction structure via the first electrode structure, wherein the first source or drain region is coupled to the second electrode structure, and a select line coupled to the transistor via the second source or drain region.

In one or more third embodiments, further to the first embodiment or the second embodiment, the one of the FE oxide or the FE semiconductor is the FE oxide.

In one or more fourth embodiments, further to the third embodiment, the FE oxide comprises hafnium (Hf), oxygen (O), and one of silicon (Si), germanium (Ge), nitrogen (N), aluminum (Al), yttrium (Y), gadolinium (Gd), or lanthanum (La).

In one or more fifth embodiments, further to the fourth embodiment, a thickness of one of the first electrode structure or the second electrode structure is in a range of 5 nanometers (nm) to 30 nm, and wherein a thickness of the FE oxide is equal to or less than 0.5 nm.

In one or more sixth embodiments, further to the third embodiment, the FE resistive junction structure further comprises a first dielectric layer between the FE oxide and the first electrode structure.

In one or more seventh embodiments, further to the sixth embodiment, the FE resistive junction structure further comprises a second dielectric layer between the FE oxide and the second electrode structure.

In one or more eighth embodiments, further to the first embodiment or the second embodiment, the one of the FE oxide or the FE semiconductor is the FE semiconductor.

In one or more ninth embodiments, further to the eighth embodiment, the FE semiconductor comprises indium (In) and selenium (Se).

In one or more tenth embodiments, further to the ninth embodiment, a thickness of one of the first electrode structure or the second electrode structure is in a range of 5 nanometers (nm) to 30 nm, and wherein a thickness of the FE semiconductor is in a range of 3 nm to 70 nm.

In one or more eleventh embodiments, further to the eighth embodiment, the FE resistive junction structure further comprises a first dielectric layer between the FE semiconductor and the first electrode structure.

In one or more twelfth embodiments, further to the eleventh embodiment, the FE resistive junction structure further comprises a second dielectric layer between the FE semiconductor and the second electrode structure.

In one or more thirteenth embodiments, a method for providing a memory device comprises forming a transistor of a memory cell, wherein the transistor comprises a gate terminal, a first source or drain terminal, and a second source or drain terminal, forming a ferroelectric (FE) resistive junction structure of the memory cell, the FE resistive junction structure comprising a first electrode structure, a second electrode structure, and a layer of one of a FE oxide or a FE semiconductor between the first electrode structure and the second electrode structure, coupling a word line to the transistor via the gate terminal, coupling a bit line to the FE resistive junction structure via the first electrode structure, wherein the first source or drain region is coupled to the second electrode structure, and coupling a select line to the transistor via the second source or drain region.

In one or more fourteenth embodiments, further to the thirteenth embodiment, the one of the FE oxide or the FE semiconductor is the FE oxide.

In one or more fifteenth embodiments, further to the fourteenth embodiment, the FE oxide comprises hafnium (Hf), oxygen (O), and one of silicon (Si), germanium (Ge), nitrogen (N), aluminum (Al), yttrium (Y), gadolinium (Gd), or lanthanum (La).

In one or more sixteenth embodiments, further to the fifteenth embodiment, a thickness of one of the first electrode structure or the second electrode structure is in a range of 5 nanometers (nm) to 30 nm, and wherein a thickness of the FE oxide is equal to or less than 0.5 nm.

In one or more seventeenth embodiments, further to the fourteenth embodiment, the FE resistive junction structure further comprises a first dielectric layer between the FE oxide and the first electrode structure.

In one or more eighteenth embodiments, further to the seventeenth embodiment, the FE resistive junction structure further comprises a second dielectric layer between the FE oxide and the second electrode structure.

In one or more nineteenth embodiments, further to the thirteenth embodiment, the one of the FE oxide or the FE semiconductor is the FE semiconductor.

In one or more twentieth embodiments, further to the nineteenth embodiment, the FE semiconductor comprises indium (In) and selenium (Se).

In one or more twenty-first embodiments, further to the twentieth embodiment, a thickness of one of the first electrode structure or the second electrode structure is in a range of 5 nanometers (nm) to 30 nm, and wherein a thickness of the FE semiconductor is in a range of 3 nm to 70 nm.

In one or more twenty-second embodiments, further to the nineteenth embodiment, the FE resistive junction structure further comprises a first dielectric layer between the FE semiconductor and the first electrode structure.

In one or more twenty-third embodiments, further to the twenty-second embodiment, the FE resistive junction structure further comprises a second dielectric layer between the FE semiconductor and the second electrode structure.

In one or more twenty-fourth embodiments, a system comprises a microprocessor comprising circuitry to execute an instruction, a memory device coupled to the microprocessor, the memory device comprising a memory cell comprising a transistor, a ferroelectric (FE) resistive junction structure coupled to the transistor, the FE resistive junction structure comprising a first electrode structure, a second electrode structure, and a layer of one of a FE oxide or a FE semiconductor between the first electrode structure and the second electrode structure.

In one or more twenty-fifth embodiments, further to the twenty-fourth embodiment, the transistor comprises a gate terminal, a first source or drain terminal, and a second source or drain terminal, the memory device further comprises a word line coupled to the transistor via the gate terminal, a bit line coupled to the FE resistive junction structure via the first electrode structure, wherein the first source or drain region is coupled to the second electrode structure, and a select line coupled to the transistor via the second source or drain region.

In one or more twenty-sixth embodiments, further to the twenty-fourth embodiment or the twenty-fifth embodiment, the one of the FE oxide or the FE semiconductor is the FE oxide.

In one or more twenty-seventh embodiments, further to the twenty-sixth embodiment, the FE oxide comprises hafnium (Hf), oxygen (O), and one of silicon (Si), germanium (Ge), nitrogen (N), aluminum (Al), yttrium (Y), gadolinium (Gd), or lanthanum (La).

In one or more twenty-eighth embodiments, further to the twenty-seventh embodiment, a thickness of one of the first electrode structure or the second electrode structure is in a range of 5 nanometers (nm) to 30 nm, and wherein a thickness of the FE oxide is equal to or less than 0.5 nm.

In one or more twenty-ninth embodiments, further to the twenty-sixth embodiment, the FE resistive junction structure further comprises a first dielectric layer between the FE oxide and the first electrode structure.

In one or more thirtieth embodiments, further to the twenty-ninth embodiment, the FE resistive junction structure further comprises a second dielectric layer between the FE oxide and the second electrode structure.

In one or more thirty-first embodiments, further to the twenty-fourth embodiment or the twenty-fifth embodiment, the one of the FE oxide or the FE semiconductor is the FE semiconductor.

In one or more thirty-second embodiments, further to the thirty-first embodiment, the FE semiconductor comprises indium (In) and selenium (Se).

In one or more thirty-third embodiments, further to the thirty-second embodiment, a thickness of one of the first electrode structure or the second electrode structure is in a range of 5 nanometers (nm) to 30 nm, and wherein a thickness of the FE semiconductor is in a range of 3 nm to 70 nm.

In one or more thirty-fourth embodiments, further to the thirty-first embodiment, the FE resistive junction structure further comprises a first dielectric layer between the FE semiconductor and the first electrode structure.

In one or more thirty-fifth embodiments, further to the thirty-fourth embodiment, the FE resistive junction structure further comprises a second dielectric layer between the FE semiconductor and the second electrode structure.

Techniques and architectures for providing a data storage device are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A memory device comprising:
a memory cell comprising:
a transistor;
a ferroelectric (FE) resistive junction structure coupled to the transistor, the FE resistive junction structure comprising:
a first electrode structure;
a second electrode structure; and
a layer of one of a FE oxide or a FE semiconductor between the first electrode structure and the second electrode structure.

2. The memory device of claim 1, wherein the transistor comprises a gate terminal, a first source or drain terminal, and a second source or drain terminal, the memory device further comprising:
a word line coupled to the transistor via the gate terminal;
a bit line coupled to the FE resistive junction structure via the first electrode structure, wherein the first source or drain region is coupled to the second electrode structure; and
a select line coupled to the transistor via the second source or drain region.

3. The memory device of claim 1, wherein the one of the FE oxide or the FE semiconductor is the FE oxide.

4. The memory device of claim 3, wherein the FE oxide comprises hafnium (Hf), oxygen (O), and one of silicon (Si), germanium (Ge), nitrogen (N), aluminum (Al), yttrium (Y), gadolinium (Gd), or lanthanum (La).

5. The memory device of claim 4, wherein a thickness of one of the first electrode structure or the second electrode structure is in a range of 5 nanometers (nm) to 30 nm, and wherein a thickness of the FE oxide is equal to or less than 0.5 nm.

6. The memory device of claim 3, wherein the FE resistive junction structure further comprises a first dielectric layer between the FE oxide and the first electrode structure.

7. The memory device of claim 6, wherein the FE resistive junction structure further comprises a second dielectric layer between the FE oxide and the second electrode structure.

8. The memory device of claim 1, wherein the one of the FE oxide or the FE semiconductor is the FE semiconductor.

9. The memory device of claim 8, wherein the FE semiconductor comprises indium (In) and selenium (Se).

10. The memory device of claim 9, wherein a thickness of one of the first electrode structure or the second electrode structure is in a range of 5 nanometers (nm) to 30 nm, and wherein a thickness of the FE semiconductor is in a range of 3 nm to 70 nm.

11. The memory device of claim 8, wherein the FE resistive junction structure further comprises a first dielectric layer between the FE semiconductor and the first electrode structure.

12. The memory device of claim 11, wherein the FE resistive junction structure further comprises a second dielectric layer between the FE semiconductor and the second electrode structure.

13. A method for providing memory device, the method comprising:
forming a transistor of a memory cell, wherein the transistor comprises a gate terminal, a first source or drain terminal, and a second source or drain terminal;
forming a ferroelectric (FE) resistive junction structure of the memory cell, the FE resistive junction structure comprising a first electrode structure, a second electrode structure, and a layer of one of a FE oxide or a FE semiconductor between the first electrode structure and the second electrode structure;
coupling a word line to the transistor via the gate terminal;
coupling a bit line to the FE resistive junction structure via the first electrode structure, wherein the first source or drain region is coupled to the second electrode structure; and
coupling a select line to the transistor via the second source or drain region.

14. The method of claim 13, wherein the one of the FE oxide or the FE semiconductor is the FE oxide.

15. The method of claim 14, wherein the FE oxide comprises hafnium (Hf), oxygen (O), and one of silicon (Si), germanium (Ge), nitrogen (N), aluminum (Al), yttrium (Y), gadolinium (Gd), or lanthanum (La).

16. The method of claim 13, wherein the one of the FE oxide or the FE semiconductor is the FE semiconductor.

17. The method of claim 16, wherein the FE semiconductor comprises indium (In) and selenium (Se).

18. A system comprising:
a microprocessor comprising circuitry to execute an instruction;
a memory device coupled to the microprocessor, the memory device comprising:
a memory cell comprising:
a transistor;
a ferroelectric (FE) resistive junction structure coupled to the transistor, the FE resistive junction structure comprising:
a first electrode structure;
a second electrode structure; and
a layer of one of a FE oxide or a FE semiconductor between the first electrode structure and the second electrode structure.

19. The system of claim 18, wherein the transistor comprises a gate terminal, a first source or drain terminal, and a second source or drain terminal, the memory device further comprising:
a word line coupled to the transistor via the gate terminal;
a bit line coupled to the FE resistive junction structure via the first electrode structure, wherein the first source or drain region is coupled to the second electrode structure; and
a select line coupled to the transistor via the second source or drain region.

20. The system of claim 18, wherein:
the FE oxide comprises hafnium (Hf), oxygen (O), and one of silicon (Si), germanium (Ge), nitrogen (N), aluminum (Al), yttrium (Y), gadolinium (Gd), or lanthanum (La); or
the FE semiconductor comprises indium (In) and selenium (Se).
